(19) United States
(12) Patent Application Publication
(10) Pub. No.: US 2025/0280630 A1
(43) Pub. Date: Sep. 4, 2025

(54) LIGHT-EMITTING SEMICONDUCTOR STRUCTURE AND MANUFACTURING METHOD THEREOF

(71) Applicant: Avision Inc., Hsinchu (TW)

(72) Inventor: Jian-Zhi Wang, Hsinchu (TW)

(21) Appl. No.: 18/966,405

(22) Filed: Dec. 3, 2024

(30) Foreign Application Priority Data
Mar. 4, 2024 (TW) 113107787

(51) Int. Cl. H10H 20/824; H10H 20/01; H10H 20/812; H10H 20/816

(52) U.S. Cl. CPC H10H 20/824; H10H 20/013; H10H 20/017; H10H 20/034; H10H 20/812; H10H 20/8162

(57) ABSTRACT

A light-emitting semiconductor structure includes a substrate, an anode electrode, an epitaxial structure, a gate electrode, and a cathode electrode. The anode electrode is disposed on a lower surface of the substrate. The epitaxial structure is disposed on an upper surface of the substrate. The epitaxial structure includes a first P-type semiconductor layer, a first N-type semiconductor layer, a second P-type semiconductor layer, a second N-type semiconductor layer and a light-emitting layer. The first P-type semiconductor layer is disposed on the upper surface of the substrate. The first N-type semiconductor layer is disposed on the first P-type semiconductor layer. The second P-type semiconductor layer is disposed on the first N-type semiconductor layer. The second N-type semiconductor layer is disposed on the second P-type semiconductor layer. The light-emitting layer is disposed between the second P-type semiconductor layer and the second N-type semiconductor layer.

### CROSS-REFERENCE TO RELATED APPLICATION

This non-provisional application claims priority under 35 U.S.C. § 119 (a) to patent application No. 113107787 filed in Taiwan, R.O.C. on Mar. 4, 2024, the entire contents of which are hereby incorporated by reference.

### BACKGROUND

### Technical Field

The present invention relates to semiconductor structures, in particular a light-emitting semiconductor structure.

### Related Art

In general, the light-emitting component of an LED print head (LPH) is realized using epitaxial structures. As known to the inventor, an epitaxial structure for realizing the light-emitting component includes a light-emitting thyristor with a PNPN structure, where the light-emitting thyristor from bottom to top has a P-type semiconductor, an N-type semiconductor, another P-type semiconductor, and another N-type semiconductor.

However, the epitaxial structure of light-emitting thyristors known to the inventor still has a large room for improvement in terms of light-emitting efficiency. Moreover, during the etching process steps in manufacturing the epitaxial structure of light-emitting thyristors, the surface and edge sidewalls of the epitaxial component are often damaged or affected, thereby affecting the driving characteristics, IV curve, and impedance characteristics of the epitaxial component. In addition, due to the higher number of defects at the edges of the semiconductor, the injection of electrons and holes into the epitaxial component is often affected by the trapping of the defect at the edges of the semiconductor, causing the edges of the light-emitting thyristor to be unable to effectively emit light, thus affecting the overall light-emitting efficiency of the component.

### SUMMARY

In some embodiments, a light-emitting semiconductor structure comprises a substrate, an anode electrode, an epitaxial structure, a gate electrode, and a cathode electrode. The anode electrode is disposed on a lower surface of the substrate. The epitaxial structure is disposed on an upper surface of the substrate. The epitaxial structure comprises a first P-type semiconductor layer, a first N-type semiconductor layer, a second P-type semiconductor layer, a second N-type semiconductor layer, and a light-emitting layer. The first P-type semiconductor layer is disposed on the upper surface of the substrate. The first N-type semiconductor layer is disposed on the first P-type semiconductor layer. The second P-type semiconductor layer is disposed on the first N-type semiconductor layer. The second N-type semiconductor layer is disposed on the second P-type semiconductor layer. The light-emitting layer is disposed between the second P-type semiconductor layer and the second N-type semiconductor layer. The gate electrode is disposed on an upper surface of the second P-type semiconductor layer. The cathode electrode is disposed on an upper surface of the second N-type semiconductor layer.

In some embodiments, the light-emitting layer is a multiple quantum well layer. The multiple quantum well layer comprises a plurality of energy well layers and a plurality of energy barrier layers. The energy well layers and the energy barrier layers are stacked in sets.

In some embodiments, the light-emitting layer is an intrinsic semiconductor layer.

In some embodiments, the number of the energy well layers and the number of the energy barrier layers are each in a range between 5 and 30. The material of the energy well layers is gallium arsenide (GaAs). The material of the energy barrier layers is aluminum gallium arsenide (AlGaAs) or indium gallium phosphide (InGaP).

In some embodiments, the light-emitting semiconductor structure further comprises a current flow confinement layer disposed between the light-emitting layer and the second P-type semiconductor layer or between the light-emitting layer and the second N-type semiconductor layer. The current flow confinement layer comprises a peripheral insulative region and a central conductive region.

In some embodiments, the peripheral insulative region is disposed right below the cathode electrode.

In some embodiments, the material of the current flow confinement layer is aluminum arsenide (AlAs). The peripheral insulative region is formed by oxidizing aluminum (Al) in the current flow confinement layer.

In some embodiments, the first P-type semiconductor layer comprises a first buffer layer, a second buffer layer, and an anode layer. The first buffer layer is disposed on the upper surface of the substrate. The second buffer layer is disposed on the first buffer layer. The anode layer is disposed on the second buffer layer.

In some embodiments, the second N-type semiconductor layer comprises a blocking layer, a cathode layer, and a covering layer. The blocking layer is disposed on an upper surface of the light-emitting layer. The cathode layer is disposed on the blocking layer. The covering layer is disposed on the cathode layer.

In some embodiments, a manufacturing method of a light-emitting semiconductor structure comprises forming a cathode electrode on an upper surface of a semiconductor substrate structure, wherein the semiconductor substrate structure comprises a substrate, a first P-type semiconductor layer, a first N-type semiconductor layer, a second P-type semiconductor layer, a second N-type semiconductor layer, a light-emitting layer, a current flow confinement layer, and a highly doped P-type semiconductor layer, the first P-type semiconductor layer is disposed on an upper surface of the substrate, the first N-type semiconductor layer is disposed on the first P-type semiconductor layer, the second P-type semiconductor layer is disposed on the first N-type semiconductor layer, the second N-type semiconductor layer is disposed on the second P-type semiconductor layer, the light-emitting layer is disposed between the second P-type semiconductor layer and the second N-type semiconductor layer, the current flow confinement layer is disposed between the light-emitting layer and the second P-type semiconductor layer, and the highly doped P-type semiconductor layer is disposed between the light-emitting layer and the current flow confinement layer; forming a protective layer on exposed surfaces of the cathode electrode and the semiconductor substrate structure; performing a first dry etching step to form a first trench on one of two sides of a predetermined light-emitting part of the semiconductor substrate structure and a second trench on the other side of the predetermined light-emitting part of the semiconductor substrate structure, wherein the first trench and the second trench extend from the protective layer to the second P-type semiconductor layer without penetrating through the second P-type semiconductor layer; oxidizing a side surface of the current flow confinement layer through the first trench and the second trench; performing a second dry etching step to form a third trench on one of two sides of a predetermined switching part of the semiconductor substrate structure and a fourth trench on the other side of the predetermined switching part of the semiconductor substrate structure, and to allow the second trench to penetrate through the second P-type semiconductor layer and the first N-type semiconductor layer and allow the second trench to extend to the first P-type semiconductor layer without penetrating through the first P-type semiconductor layer, wherein the third trench is formed between the first trench and the predetermined switching part, and the third trench and the fourth trench extend from the protective layer to the second P-type semiconductor layer without penetrating through the second P-type semiconductor layer; forming a plurality of gate electrodes on a bottom surface of the third trench and a bottom surface of the fourth trench; performing a third dry etching step to form a fifth trench between two adjacent gate electrodes of the fourth trench, and to allow the second trench to penetrate through the first P-type semiconductor layer and to allow the second trench to extend to the substrate without penetrating through the substrate, wherein the fifth trench extends from the bottom surface of the fourth trench to the first P-type semiconductor layer without penetrating through the first P-type semiconductor layer; conformally forming a passivation layer on the exposed surfaces of the cathode electrode and the semiconductor substrate structure and on exposed surfaces of the gate electrodes after the third dry etching step; performing a fourth dry etching step after depositing the passivation layer on the exposed surfaces of the cathode electrode and the semiconductor substrate structure and on the exposed surfaces of the gate electrodes to form a cathode opening above the cathode electrode and a gate opening above each of the gate electrodes; and forming a circuit layer on the passivation layer, wherein the circuit layer is electrically connected to the cathode electrode via the cathode opening and electrically connected to the gate electrode via the gate opening.

The following will describe the detailed features and advantages of the instant disclosure in detail in the detailed description. The content of the description is sufficient for any person skilled in the art to comprehend the technical context of the instant disclosure and to implement it accordingly. According to the content, claims and drawings disclosed in the instant specification, any person skilled in the art can readily understand the goals and advantages of the instant disclosure.

### BRIEF DESCRIPTION OF THE DRAWINGS

The disclosure will become more fully understood from the detailed description given herein below for illustration only, and thus not limitative of the disclosure, wherein:

FIG. 1 illustrates a schematic cross-sectional view of an embodiment of a light-emitting semiconductor structure.

FIG. 2 illustrates a schematic cross-sectional view of an embodiment of a light-emitting layer.

FIG. 3 illustrates a line graph showing the comparison between the luminous intensity of the light-emitting semiconductor structure and the luminous intensity of the semiconductor structure known to the inventor.

FIG. 4A illustrates a schematic cross-sectional view of another embodiment of the light-emitting semiconductor structure.

FIG. 4B illustrates a schematic cross-sectional view of yet another embodiment of the light-emitting semiconductor structure.

FIG. 5A illustrates a schematic cross-sectional view of still yet another embodiment of a light-emitting semiconductor structure.

FIG. 5B illustrates a schematic cross-sectional view of a further embodiment of the light-emitting semiconductor structure.

FIG. 6 illustrates a top view of an embodiment of a light-emitting semiconductor array chip unit.

FIG. 7 illustrates a cross-sectional view along section line 7 of the light-emitting semiconductor array chip unit of FIG. 6.

FIG. 8A to 8I illustrate schematic views of steps of an embodiment of a manufacturing method of the light-emitting semiconductor structure.

FIG. 9 illustrates a flow chart of an embodiment of the manufacturing method of the light-emitting semiconductor structure.

### DETAILED DESCRIPTION

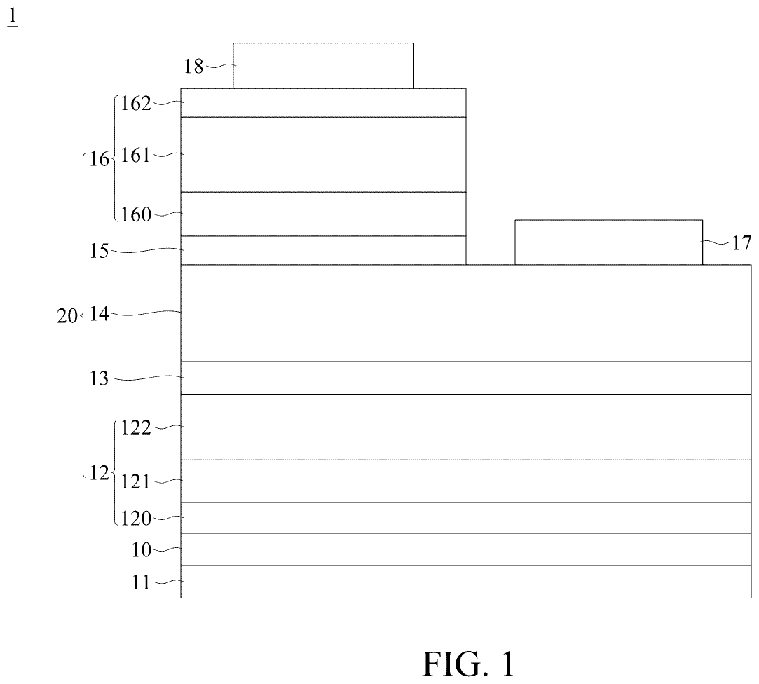

FIG. 1 illustrates a schematic cross-sectional view of an embodiment of a light-emitting semiconductor structure 1. Please refer to FIG. 1. The light-emitting semiconductor structure 1 comprises a substrate 10, an anode electrode 11, an epitaxial structure 20, a gate electrode 17, and a cathode electrode 18. The anode electrode 11 is disposed on a lower surface of the substrate 10. The epitaxial structure 20 is disposed on an upper surface of the substrate 10. The epitaxial structure 20 comprises a first P-type semiconductor layer 12, a first N-type semiconductor layer 13, a second P-type semiconductor layer 14, a second N-type semiconductor layer 16, and a light-emitting layer 15. The first P-type semiconductor layer 12 is disposed on the upper surface of the substrate 10. The first N-type semiconductor layer 13 is disposed on the first P-type semiconductor layer 12. The second P-type semiconductor layer 14 is disposed on the first N-type semiconductor layer 13. The second N-type semiconductor layer 16 is disposed on the second P-type semiconductor layer 14. The light-emitting layer 15 is disposed between the second P-type semiconductor layer 14 and the second N-type semiconductor layer 16. The gate electrode 17 is disposed on an upper surface of the second P-type semiconductor layer 14. The cathode electrode 18 is disposed on an upper surface of the second N-type semiconductor layer 16.

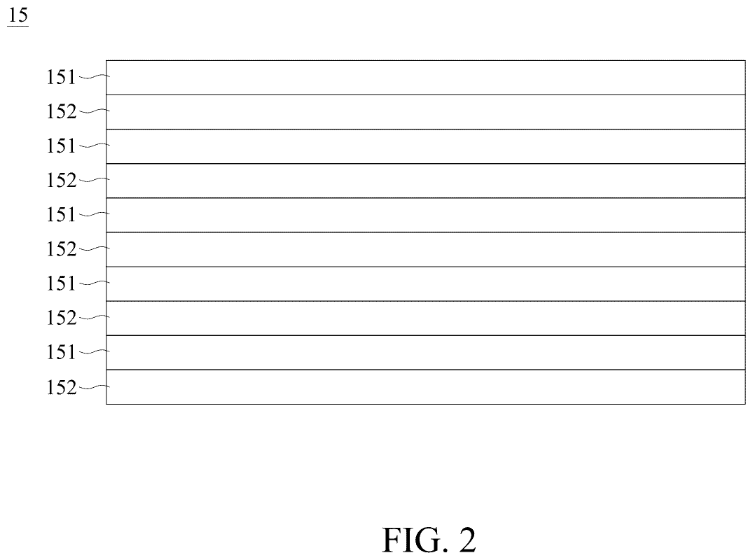

FIG. 2 illustrates a schematic cross-sectional view of an embodiment of the light-emitting layer 15. Please refer to FIG. 1 and FIG. 2. The light-emitting layer 15 comprises a plurality of energy well layers 151 and a plurality of energy barrier layers 152. The energy well layers 151 and the energy barrier layers 152 are stacked in sets. In the embodiment shown in FIG. 2, the light-emitting layer 15 comprises five quantum well layers 151 and five barrier layers 152, but the number of the energy well layers 151 and the number of the energy barrier layers 152 are not limited thereto. In some embodiments, the number of the energy well layers 151 and the number of the energy barrier layers 152 are each in a range between 5 and 30.

In some embodiments, the material of the quantum well layers 151 may be, but not limited to, gallium arsenide (GaAs), and the material of the barrier layers 152 may be, but not limited to, aluminum gallium arsenide (AlGaAs) or indium gallium phosphide (InGaP).

In some embodiments, the light-emitting layer 15 is an intrinsic semiconductor layer. That is, in these embodiments, the light-emitting layer 15 is a non-doped, pure semiconductor with an intact lattice structure. The concentration of free electrons (negatively charged carriers) and the concentration of holes (positively charged carriers) for performing conduction in the light-emitting layer 15 are equal and in a state of equilibrium. In other words, in some embodiments, the epitaxial structure 20 is a PNPIN structure rather than a PNPN structure.

In some embodiments, the material of the substrate 10 may be, but not limited to, GaAs. The material of the anode electrode 11 may be, but not limited to, chromium (Cr) or gold (Au). The material of the gate electrode 17 may be, but not limited to, Au or gold-zinc alloy (AuZn). The material of the cathode electrode 18 may be, but not limited to, Au, germanium (Ge), or nickel (Ni).

In some embodiments, the first P-type semiconductor layer 12 comprises a first buffer layer 120, a second buffer layer 121, and an anode layer 122. The first buffer layer 120 is disposed on the upper surface of the substrate 10. The second buffer layer 121 is disposed on the first buffer layer 120. The anode layer 122 is disposed on the second buffer layer 121. In some embodiments, the material of the first buffer layer 120 may be, but not limited to, GaAs. The materials of the second buffer layer 121 and the anode layer 122 may be, but not limited to, AlGaAs.

In some embodiments, the second N-type semiconductor layer 16 comprises a blocking layer 160, a cathode layer 161, and a covering layer 162. The blocking layer 160 is disposed on an upper surface of the light-emitting layer 15. The cathode layer 161 is disposed on the blocking layer 160. The covering layer 162 is disposed on the cathode layer 161. In some embodiments, the material of the covering layer 162 may be, but not limited to, GaAs. The material of the blocking layer 160 and the cathode layer 161 may be, but not limited to, AlGaAs.

In some embodiments, the thickness of the substrate 10 may be, but not limited to, 300 micrometers (μm). The thickness of the first buffer layer 120 may be, but not limited to, 100 nanometers (nm). The thickness of the second buffer layer 121 may be, but not limited to, 250 nm. The thickness of the anode layer 122 may be, but not limited to, 400 nm. The thickness of the first N-type semiconductor layer 13 may be, but not limited to, 320 nm. The thickness of the second P-type semiconductor layer 14 may be, but not limited to, 680 nm. The thickness of the blocking layer 160 may be, but not limited to, 15 nm. The thickness of the cathode layer 161 may be, but not limited to, 560 nm. The thickness of the covering layer 162 may be, but not limited to, 25 nm.

In some embodiments, the wavelength of the light emitted by the epitaxial structure 20 ranges from 760 nm to 820 nm.

Table 1 below shows the materials, compositions, carrier types, and dopants of each of the layers in an embodiment of the light-emitting semiconductor structure 1, but the present invention is not limited thereto.

TABLE 1

| | | Composi- | Carrier | Dop- |
|---|---|---|---|---|
| Layer | Material | tion | Type | ant |
| Covering layer 162 | GaAs | — | n | Si |
| Cathode layer 161 | Al(x)Ga(1 − x)As | x = 0.25 | n | Si |
| Blocking layer 160 | Al(x)Ga(1 − x)As | x = 0.35 | n | Si |
| Second P-type | Al(x)Ga(1 − x)As | x = 0.15 | p | Zn |
| semiconductor layer 14 | | | | |
| First N-type | Al(x)Ga(1 − x)As | x = 0.15 | n | Si |
| semiconductor layer 13 | | | | |
| Anode layer 122 | Al(x)Ga(1 − x)As | x = 0.35 | p | Zn |
| Second buffer layer 121 | Al(x)Ga(1 − x)As | x = 0.20 | p | Zn |
| First buffer layer 120 | GaAs | — | p | Zn |
| Substrate 10 | GaAs | — | p | Zn |

Table 2 below shows the main peak wavelength values, thickness ranges, and carrier concentration ranges for each of the layer in an embodiment of the light-emitting semiconductor structure 1, but the present invention is not limited thereto.

TABLE 2

| | Main Peak | Thickness | Carrier |
|---|---|---|---|
| | Wavelength | Range | Concentration |
| Layer | Value (nm) | (nm) | Range (cm−3) |
| Covering layer 162 | — | 10~40 | 2.00~4.00E+18 |
| Cathode layer 161 | 716 ± 8 | 500~700 | 2.00~4.00E+18 |
| Blocking layer 160 | 668 ± 8 | 10~30 | 2.00~3.00E+18 |
| Second P-type | 777 ± 4 | 600~800 | 1.00~3.00E+17 |
| semiconductor layer 14 | | | |
| First N-type | 777 ± 4 | 250~350 | 1.00~3.00E+17 |
| semiconductor layer 13 | | | |
| Anode layer 122 | 669 ± 8 | 300~500 | 2.50~4.00E+17 |
| Second buffer layer 121 | 739 ± 8 | 200~300 | 2.00~3.50E+17 |
| First buffer layer 120 | — | 50~150 | 0.5~1.5E+17 |
| Substrate 10 | — | 550000 | 3.00~7.00E+19 |

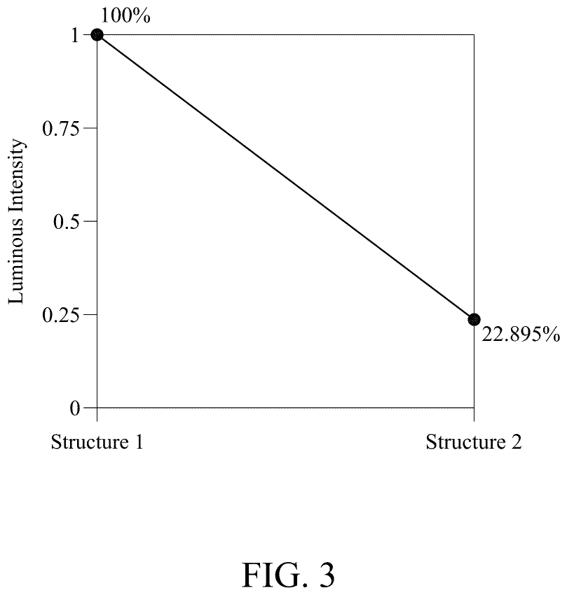

FIG. 3 illustrates a line graph showing the comparison between the luminous intensity of the light-emitting semiconductor structure 1 and the luminous intensity of the semiconductor structure known to the inventor. Please refer to FIG. 3. Structure 2 is the semiconductor structure known to the inventor that conventionally adopts a light-emitting thyristor with a PNPN structure. Structure 1 is the light-emitting semiconductor structure 1 using the epitaxial structure 20 of the PNPIN structure according to one or some embodiments of the instant disclosure. It can be seen from FIG. 3 that the luminous intensity of the light-emitting semiconductor structure 1 is approximately 4 times higher than the luminous intensity of the semiconductor structure known to the inventor. In the embodiment of FIG. 3, the number of the energy well layers 151 and the number of the energy barrier layers 152 of the light-emitting semiconductor structure 1 are both five.

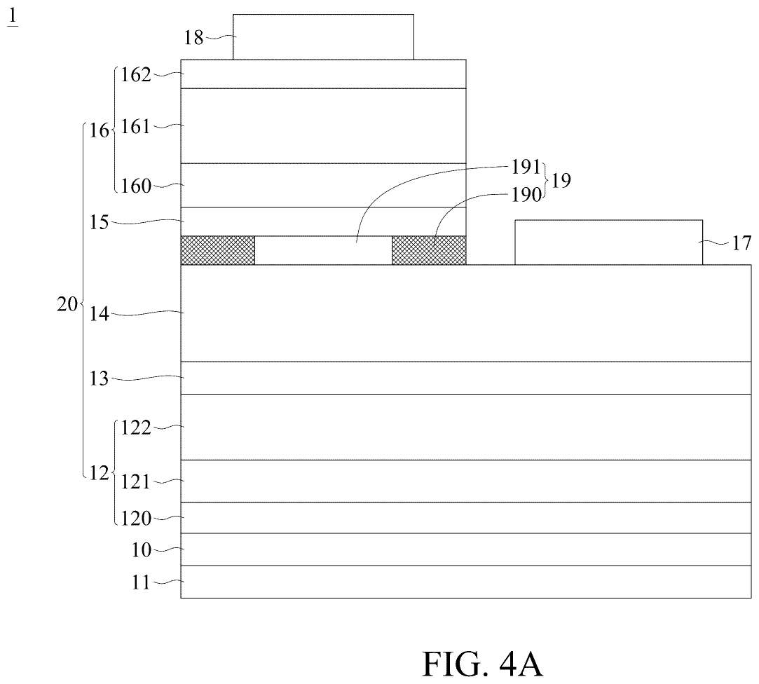

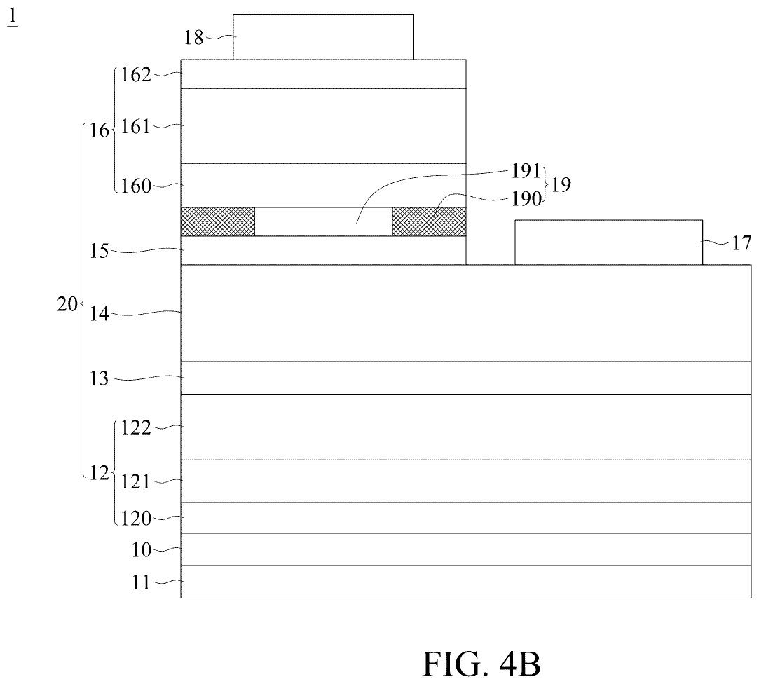

FIG. 4A illustrates a schematic cross-sectional view of another embodiment of the light-emitting semiconductor structure 1. Please refer to FIG. 4A. In some embodiments, the light-emitting semiconductor structure 1 further comprises a current flow confinement layer 19. The current flow confinement layer 19 is disposed between the light-emitting layer 15 and the second P-type semiconductor layer 14. The current flow confinement layer 19 comprises a peripheral insulative region 190 and a central conductive region 191. FIG. 4B illustrates a schematic cross-sectional view of yet another embodiment of the light-emitting semiconductor structure 1. Please refer to FIG. 4B. In some embodiments, the current flow confinement layer 19 is disposed between the light-emitting layer 15 and the second N-type semiconductor layer 16.

In some embodiments, the peripheral insulative region 190 is formed by selectively oxidizing specific elements in the material of the current flow confinement layer 19 from at least one side surface of the current flow confinement layer 19. In some embodiments, the material of the current flow confinement layer 19 may be, but not limited to, aluminum arsenide (AlAs). The peripheral insulative region 190 is formed by oxidizing aluminum (Al) in the current flow confinement layer 19, but the present invention is not limited thereto.

Due to the higher number of defects at the edges of the semiconductor, the configuration of the peripheral insulative region 190 can eliminate the defects at the edges of the current flow confinement layer 19. Hence, the current flowing through the current flow confinement layer 19 is not affected by the edge defects and concentrated in the central conductive region 191, thereby allowing the luminous efficiency of the light-emitting semiconductor structure 1 to be greatly improved.

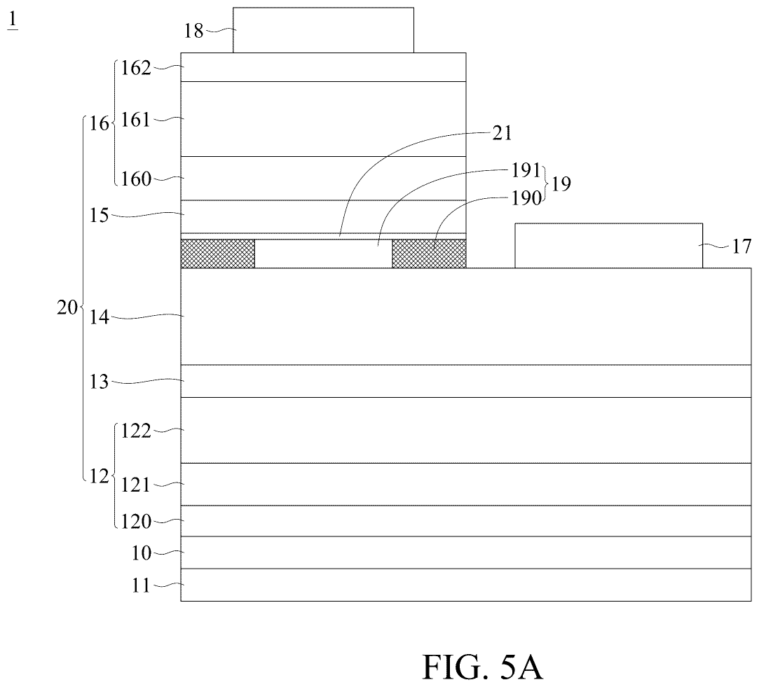

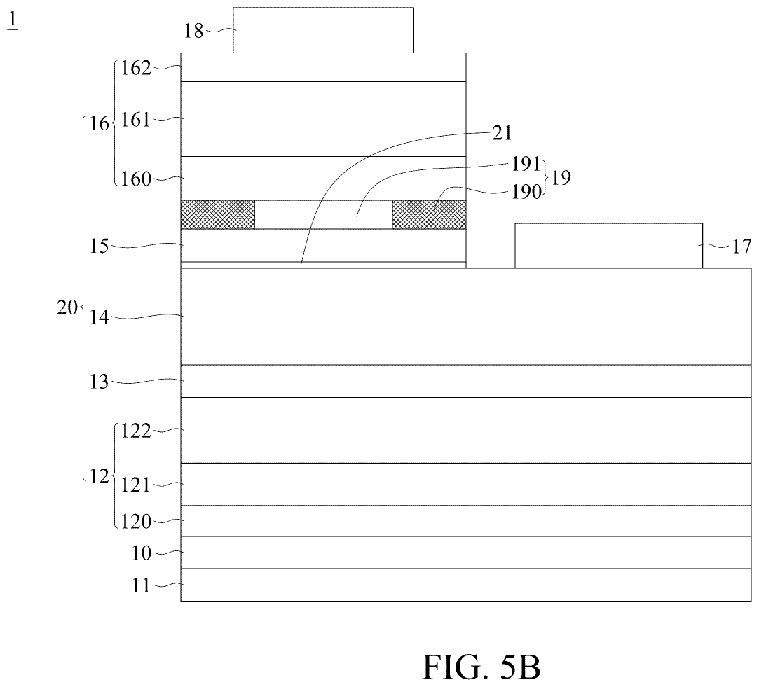

FIG. 5A illustrates a schematic cross-sectional view of still yet another embodiment of a light-emitting semiconductor structure 1. Please refer to FIG. 5A. In some embodiments, the light-emitting semiconductor structure 1 further comprises a highly doped P-type semiconductor layer 21. The highly doped P-type semiconductor layer 21 is disposed between the light-emitting layer 15 and the current flow confinement layer 19. In some embodiments, the material of the highly doped P-type semiconductor layer 21 is the same as the material of the second P-type semiconductor layer 14, and the doping concentration of the highly doped P-type semiconductor layer 21 may be, but not limited to, 10 times the doping concentration of the second P-type semiconductor layer 14. For example, if the doping concentration of the second P-type semiconductor layer 14 is 10¹⁷ (cm⁻³), then the doping concentration of the highly doped P-type semiconductor layer 21 would be 10¹⁸ (cm⁻³). FIG. 5B illustrates a schematic cross-sectional view of a further embodiment of the light-emitting semiconductor structure 1. Please refer to FIG. 5B. In some embodiments, the current flow confinement layer 19 is disposed between the light-emitting layer 15 and the second N-type semiconductor layer 16.

As known to the inventor, the driving components of light-emitting thyristors are usually disposed in the middle or lower part of the structure thereof. For example, if the structure of the light-emitting thyristor is a PNPN structure, the driving elements thereof are typically disposed in the first P-type semiconductor layer, the first N-type semiconductor layer, and the second P-type semiconductor layer thereof from the bottom up. However, during the etching step of the manufacturing process, the layer where the driving components of the light-emitting thyristor are disposed is often etched, resulting in the driving characteristics, driving voltage, IV curve, and impedance characteristics of the light-emitting thyristor being affected, thereby increasing the required time for the light-emitting thyristor to be switched on and off with a clock pulse.

On the other hand, in the light-emitting semiconductor structure 1, since the light-emitting layer 15 and the current flow confinement layer 19 are disposed above the second P-type semiconductor layer 14 where the gate electrode 17 is disposed, during manufacturing, only etching to the second P-type semiconductor layer 14 is needed. In other words, in these embodiments, the first P-type semiconductor layer 12 and the first N-type semiconductor layer 13 are not etched, and are not affected by subsequent edge oxidation insulation processes. Therefore, the turn-on clock preparation time and the turn-off clock preparation time of the light-emitting thyristor composed of the first P-type semiconductor layer 12, the first N-type semiconductor layer 13, and the second P-type semiconductor layer 14 from the substrate 10 upwards will remain relatively stable and will not be affected by etching and edge oxidation processes.

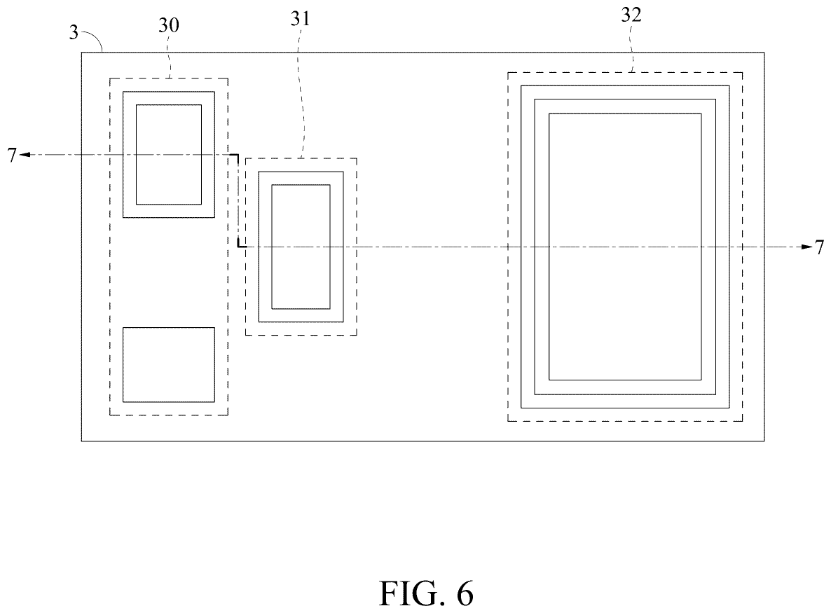

FIG. 6 illustrates a top view of an embodiment of a light-emitting semiconductor array chip unit 3. Please refer to FIG. 6. The light-emitting semiconductor array chip unit 3 comprises a transmission part 30, a parity switch part 31, and a light-emitting part 32. A light-emitting semiconductor array chip comprises a plurality of the light-emitting semiconductor array chip units 3, and the structure of the light-emitting semiconductor array chip is the light-emitting semiconductor structure 1. The number of the light-emitting semiconductor array chip units 3 comprised in the light-emitting semiconductor array chip is not limited.

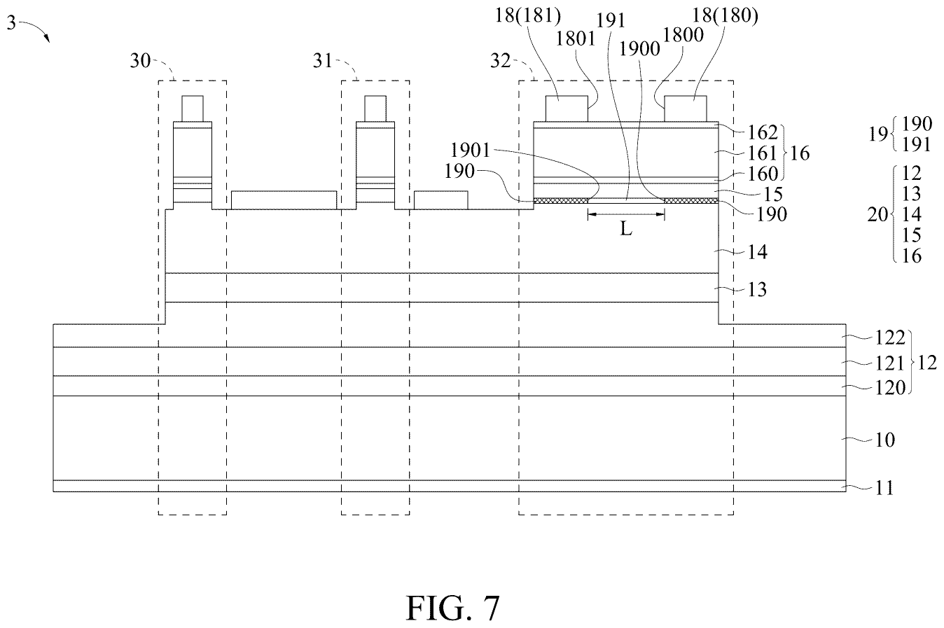

FIG. 7 illustrates a cross-sectional view along line 7-7 of the light-emitting semiconductor array chip unit 3 of FIG. 6. Please refer to FIG. 7. In some embodiments, the cathode electrode 18 of the light-emitting part 32 is a surrounding cathode electrode. Therefore, in FIG. 7 (which is a cross-sectional view of the light-emitting semiconductor array chip unit 3), the cathode electrode 18 of the light-emitting part 32 has two parts (for convenience, referred to as cathode electrode 180 and cathode electrode 181, respectively). At this point, the light-emitting region of the light-emitting part 32 is the central area surrounded by the surrounding cathode electrode 18. In some embodiments, the peripheral insulative region 190 of the light-emitting part 32 is disposed right below the cathode electrodes 180 and 181. In some embodiments, the side surface 1900 of the peripheral insulative region 190, disposed right below the cathode electrode 180 and near the center of the epitaxial structure 20, is aligned with the side surface 1800 of the cathode electrode 180 near the center of the epitaxial structure 20. Similarly, the side surface 1901 of the peripheral insulative region 190 which is disposed right below the cathode electrode 181 and near the center of the epitaxial structure 20 is aligned with the side surface 1801 of the cathode electrode 181 near the center of the epitaxial structure 20. At this point, the length L of the central conductive region 191 of the light-emitting part 32 would be the distance between the side surface 1800 of the cathode electrode 180 and the side surface 1801 of the cathode electrode 181 near the center of the epitaxial structure 20.

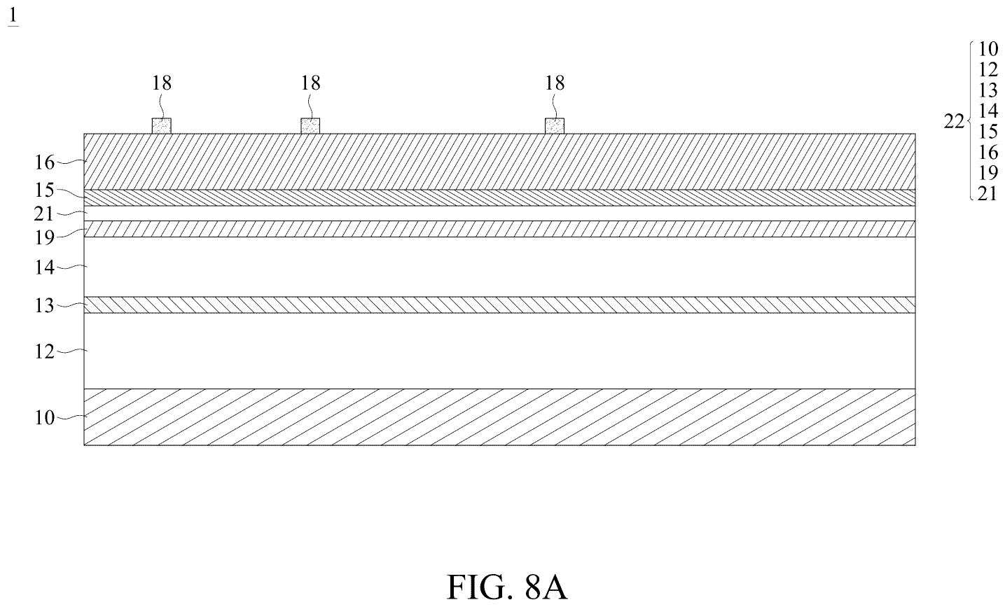

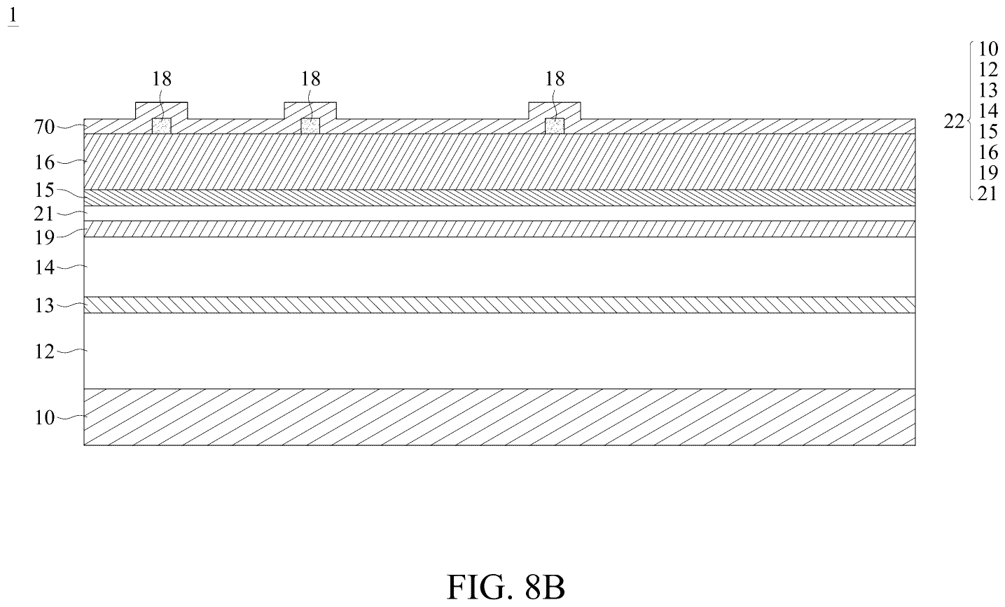

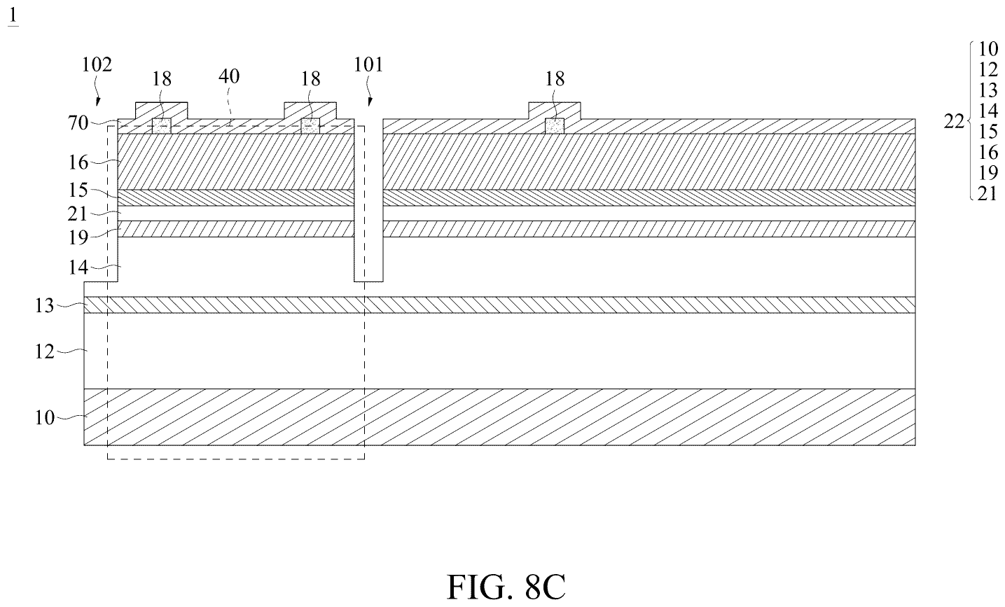

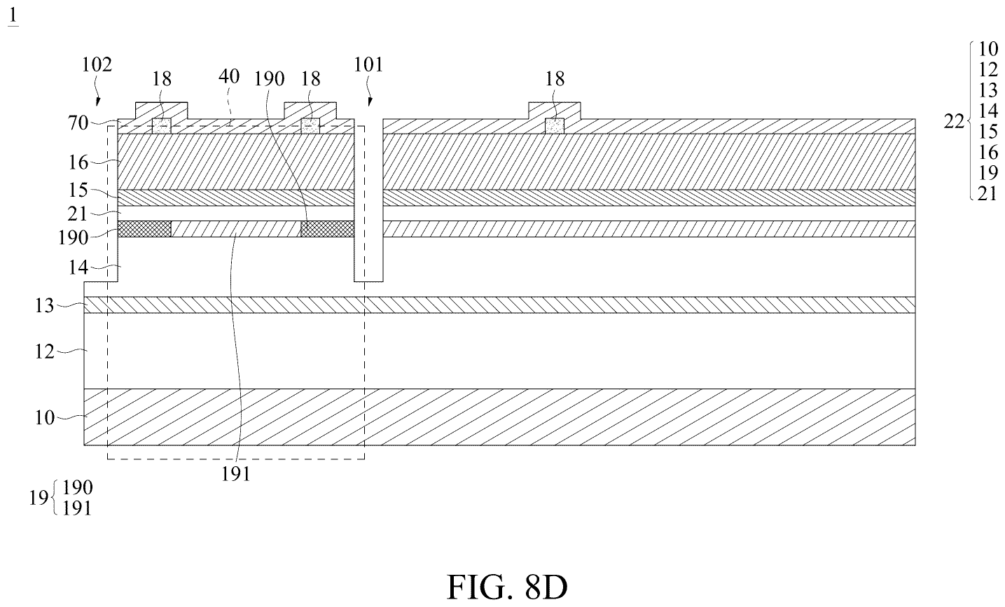

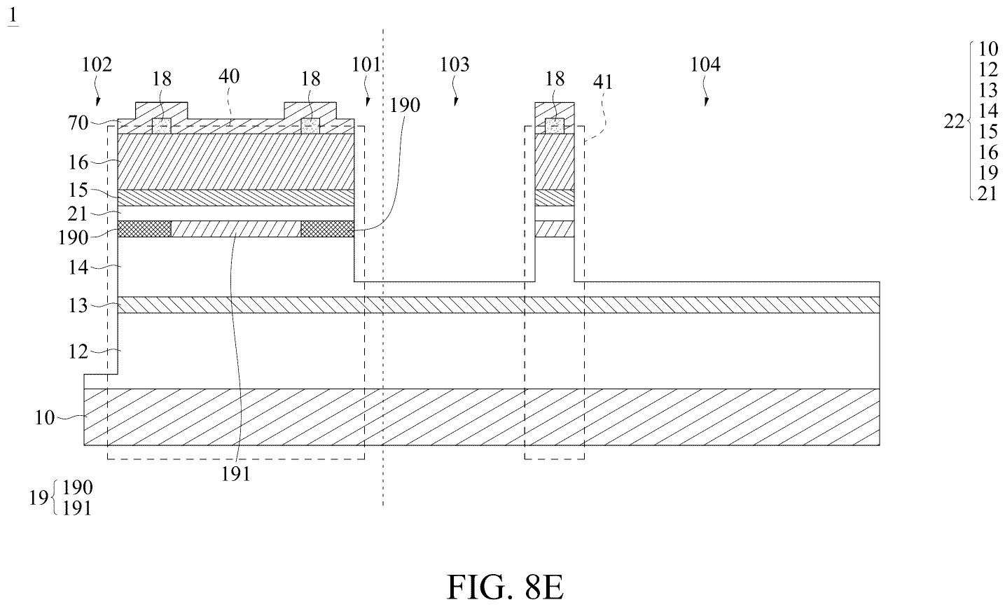

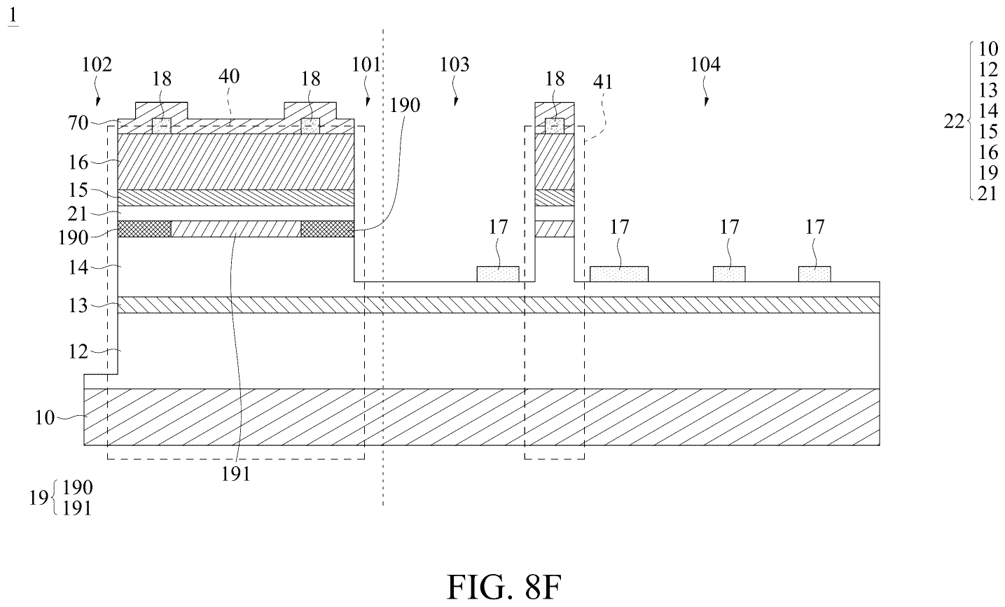

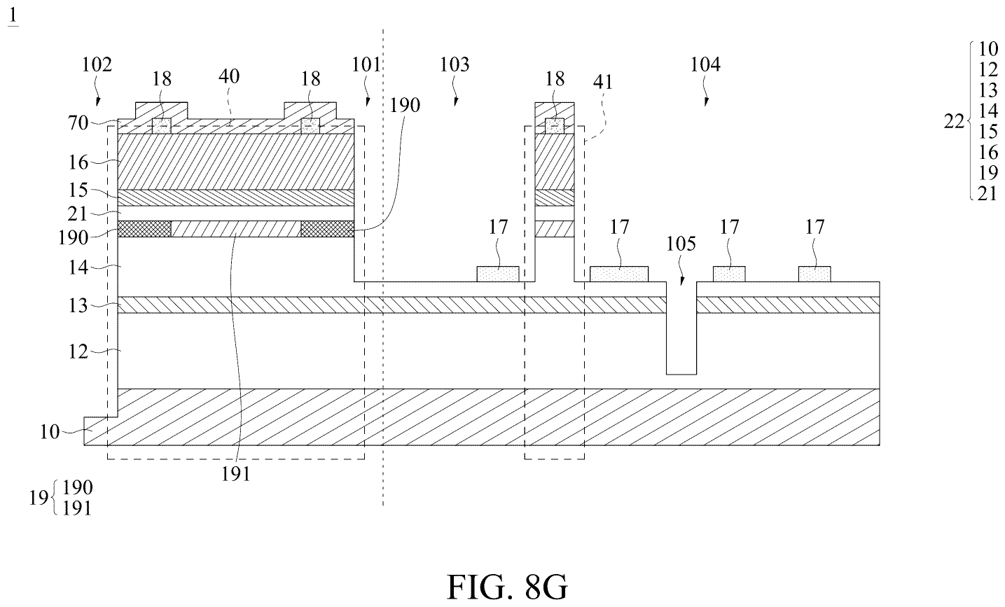

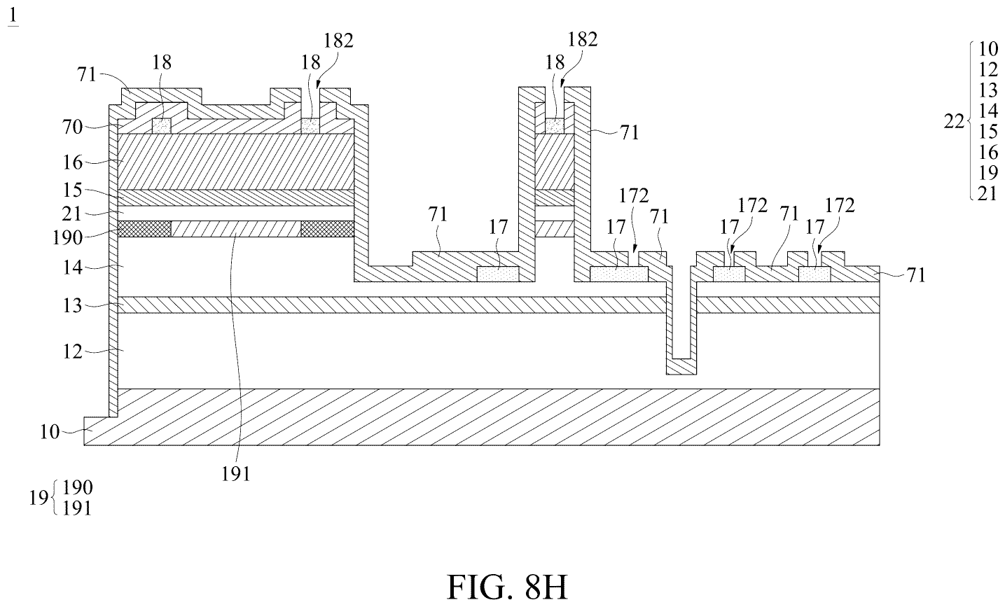

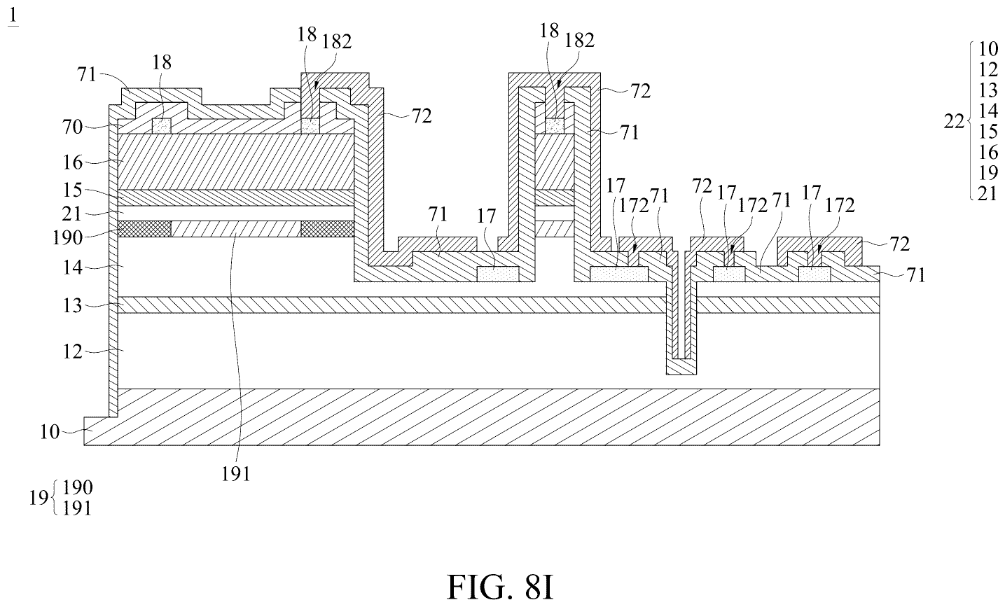

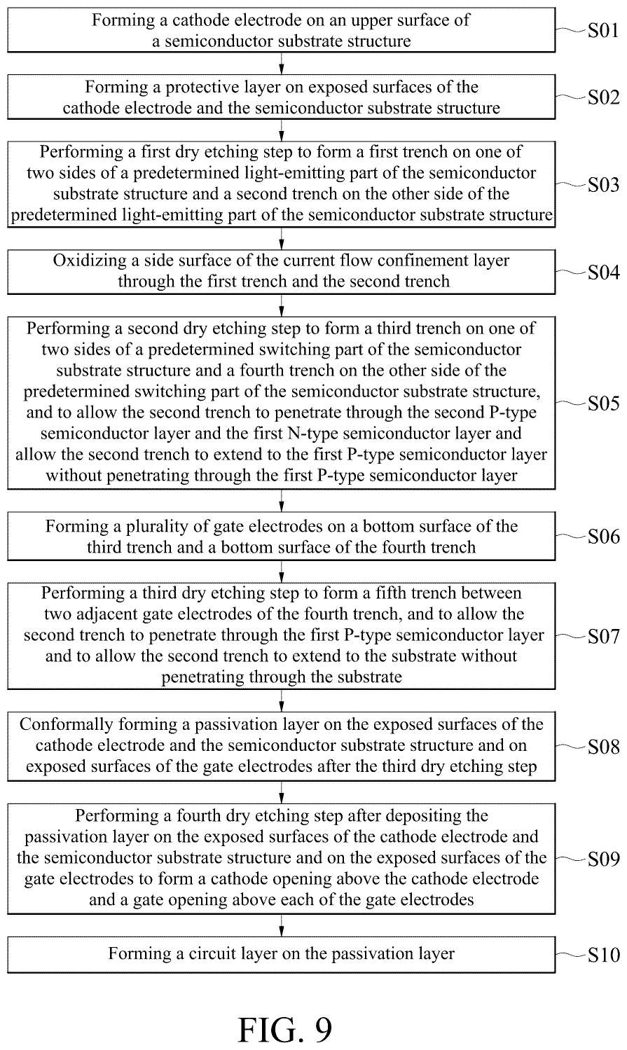

FIG. 8A to 8I illustrate schematic views of steps of an embodiment of a manufacturing method of the light-emitting semiconductor structure 1. FIG. 9 illustrates a flow chart of an embodiment of the manufacturing method of the light-emitting semiconductor structure 1. Please refer to FIG. 8A to 8I and FIG. 9. First, a cathode electrode 18 is formed on an upper surface of a semiconductor substrate structure 22 (step S01). The semiconductor substrate structure comprises a substrate 10, a first P-type semiconductor layer 12, a first N-type semiconductor layer 13, a second P-type semiconductor layer 14, a second N-type semiconductor layer 16, a light-emitting layer 15, a current flow confinement layer 19, and a highly doped P-type semiconductor layer 21. The first P-type semiconductor layer 12 is disposed on an upper surface of the substrate 10. The first N-type semiconductor layer 13 is disposed on the first P-type semiconductor layer 12. The second P-type semiconductor layer 14 is disposed on the first N-type semiconductor layer 13. The second N-type semiconductor layer 16 is disposed on the second P-type semiconductor layer 14. The light-emitting layer 15 is disposed between the second P-type semiconductor layer 14 and the second N-type semiconductor layer 16. The current flow confinement layer 19 is disposed between the light-emitting layer 15 and the second P-type semiconductor layer 14. The highly doped P-type semiconductor layer 21 is disposed between the light-emitting layer 15 and the current flow confinement layer 19 (as shown in FIG. 8A).

Next, a protective layer 70 is formed on exposed surfaces of the cathode electrode 18 and the semiconductor substrate structure 22 (step S02) (as shown in FIG. 8B). Then, a first dry etching step is performed to form a first trench 101 on one of two sides of a predetermined light-emitting part 40 of the semiconductor substrate structure 22 and a second trench 102 on the other side of the predetermined light-emitting part 40 of the semiconductor substrate structure 22 (step S03). The first trench 101 and the second trench 102 extend from the protective layer 70 to the second P-type semiconductor layer 14 without penetrating through the second P-type semiconductor layer 14 (as shown in FIG. 8C). Then, through the first trench 101 and the second trench 102, a side surface of the current flow confinement layer 19 is oxidized (step S04) (as shown in FIG. 8D).

Then, a second dry etching step is performed to form a third trench 103 on one of two sides of a predetermined switching part 41 of the semiconductor substrate structure 22 and a fourth trench 104 on the other side of the predetermined switching part 41 of the semiconductor substrate structure 22, and to allow the second trench 102 to penetrate through the second P-type semiconductor layer 14 and the first N-type semiconductor layer 13 and allow the second trench 102 to extend to the first P-type semiconductor layer 12 without penetrating through the first P-type semiconductor layer 12 (step S05). The third trench 103 is formed between the first trench 101 and the predetermined switching part 41. The third trench 103 and the fourth trench 104 extend from the protective layer 70 to the second P-type semiconductor layer 14 without penetrating through the second P-type semiconductor layer 14 (as shown in FIG. 8E). Then, a plurality of gate electrodes 17 are formed on a bottom surface of the third trench 103 and a bottom surface of the fourth trench 104 (step S06) (as shown in FIG. 8F).

Then, a third dry etching step is performed to form a fifth trench 105 between two adjacent gate electrodes 17 of the fourth trench 104, and to allow the second trench 102 to penetrate through the first P-type semiconductor layer 12 and to allow the second trench 102 to extend to the substrate 10 without penetrating through the substrate 10 (step S07). The fifth trench 105 extends from the bottom surface of the fourth trench 104 to the first P-type semiconductor layer 12 without penetrating through the first P-type semiconductor layer 12 (as shown in FIG. 8G). Then, a passivation layer 71 is conformally formed on the exposed surfaces of the cathode electrode 18 and the semiconductor substrate structure 22 and on exposed surfaces of the gate electrodes 17 after the third dry etching step (step S08). Then, a fourth dry etching step is performed after depositing the passivation layer 71 on the exposed surfaces of the cathode electrode 18 and the semiconductor substrate structure 22 and on the exposed surfaces of the gate electrodes 17 to form a cathode opening 182 above the cathode electrode 18 and a gate opening 172 above each of the gate electrodes 17 (step S09) (as shown in FIG. 8H). Finally, a circuit layer 72 is formed on the passivation layer 71 (step S10). The circuit layer 72 is electrically connected to the cathode electrode 18 via the cathode opening 182 and electrically connected to the gate electrode 17 via the gate opening 172 (as shown in FIG. 8I).

In some embodiments, the method of forming the cathode electrode 18 on the upper surface of the semiconductor substrate structure 22 (step S01) may be, but not limited to, using an electron gun to plate the metal of the cathode electrode 18 on the upper surface of the semiconductor substrate structure 22. In some embodiments, the method of forming the protective layer 70 on the exposed surfaces of the cathode electrode 18 and the semiconductor substrate structure 22 (step S02) may be, but not limited to, using chemical vapor deposition (CVD) to deposit the protective layer 70 on the exposed surfaces of the cathode electrode 18 and the semiconductor substrate structure 22. In some embodiments, the material of the protective layer 70 may be, but not limited to, silicon nitride (SiN). In some embodiments, the thickness of the protective layer 70 may be, but not limited to, 500 Å. In some embodiments, the operating temperature when using CVD to form the protective layer 70 on the exposed surfaces of the cathode electrode 18 and the semiconductor substrate structure 22 may be, but not limited to, 320° C.

In some embodiments, the depth of the first trench 101 and the depth of the second trench 102 after step S03 is performed may be, but not limited to, 7500 Å. In other words, in some embodiments, in the semiconductor substrate structure 22, the depth of the first trench 101 and the depth of the second trench 102 after step S03 is performed may be, but not limited to, 7000 Å (i.e., the depth of the first trench 101 and the depth of the second trench 102 after step S03 is performed, 7500 Å, minus the thickness of the protective layer 70, which is 500 Å).

In some embodiments, the depth of the third trench 103 and the depth of the fourth trench 104 may be, but not limited to, 7500 Å. In other words, in some embodiments, in the semiconductor substrate structure 22, the depth of the third trench 103 and the depth of the fourth trench 104 may be, but not limited to, 7000 Å (i.e., the depth of the third trench 103 and the depth of the fourth trench 104, 7500 Å, minus the thickness of the protective layer 70, which is 500 Å). In some embodiments, after step S05 is performed, the extended depth of the second trench 102 may be, but not limited to, 12000 Å. In other words, after the second dry etching step is performed, the depth of the second trench 102 may be, but not limited to, 19500 Å (i.e., the depth of the second trench 102 after step S03 is performed, 7500 Å, plus the extended depth of the second trench 102, 12000 Å). In some embodiments, after step S05 is performed, the extended depth of the second trench 102 is 11000 Å, but the present invention is not limited thereto.

In some embodiments, the method of forming the gate electrodes 17 on the bottom surfaces of the third trench 103 and the fourth trench 104 (step S06) may be, but not limited to, using thermal evaporation deposition to plate the metal of the gate electrodes 17 on the bottom surfaces of the third trench 103 and the fourth trench 104.

In some embodiments, the depth of the fifth trench 105 may be, but not limited to, 11000 Å or 12000 Å. In some embodiments, after the third dry etching step, the method of conformally forming the passivation layer 71 on the exposed surfaces of the cathode electrode 18 and the semiconductor substrate structure 22 and on exposed surfaces of the gate electrodes 17 (step S08) may be, but not limited to, using CVD to conformally form the passivation layer 71 on the exposed surfaces of the cathode electrode 18 and the semiconductor substrate structure 22 and on exposed surfaces of the gate electrodes 17. In some embodiments, the material of the passivation layer 71 may be, but not limited to, SiN. In some embodiments, the thickness of the passivation layer 71 may be, but not limited to, 2500 Å. In some embodiments, the operating temperature when using CVD to conformally form the passivation layer 71 on the exposed surfaces of the cathode electrode 18 and the semiconductor substrate structure 22 and on exposed surfaces of the gate electrodes 17 may be, but not limited to, 320° C. In some embodiments, the method of forming the circuit layer 72 on the passivation layer 71 (step S10) may be, but not limited to, using electroplating to plate the circuit layer 72 on the passivation layer 71. In some embodiments, the material of the circuit layer 72 may be, but not limited to, gold (Au).

To sum up, in some embodiments, by the configuration of the light-emitting layer 15, the luminous intensity of the light-emitting semiconductor structure 1 is approximately 4 times higher than the luminous intensity of the semiconductor structure known to the inventor. Furthermore, by the configuration of the peripheral insulative region 190 and by configuring the light-emitting layer 15 and the current flow confinement layer 19 of the light-emitting semiconductor structure 1 above the second P-type semiconductor layer 14 where the gate electrode 17 is disposed, the luminous efficiency of the light-emitting semiconductor structure 1 is further improved.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A light-emitting semiconductor structure, comprising:
a substrate;
an anode electrode disposed on a lower surface of the substrate;
an epitaxial structure disposed on an upper surface of the substrate, wherein the epitaxial structure comprises:
a first P-type semiconductor layer disposed on the upper surface of the substrate;
a first N-type semiconductor layer disposed on the first P-type semiconductor layer;
a second P-type semiconductor layer disposed on the first N-type semiconductor layer;
a second N-type semiconductor layer disposed on the second P-type semiconductor layer; and
a light-emitting layer disposed between the second P-type semiconductor layer and the second N-type semiconductor layer;
a gate electrode disposed on an upper surface of the second P-type semiconductor layer; and
a cathode electrode disposed on an upper surface of the second N-type semiconductor layer.

2. The light-emitting semiconductor structure according to claim 1, wherein the light-emitting layer is a multiple quantum well layer, the multiple quantum well layer comprises a plurality of energy well layers and a plurality of energy barrier layers, and the energy well layers and the energy barrier layers are stacked in sets.

3. The light-emitting semiconductor structure according to claim 2, wherein the light-emitting layer is an intrinsic semiconductor layer.

4. The light-emitting semiconductor according to claim 3, wherein the number of the energy well layers and the number of the energy barrier layers are each in a range between 5 and 30, the material of the energy well layers is gallium arsenide (GaAs), and the material of the energy barrier layers is aluminum gallium arsenide (AlGaAs) or indium gallium phosphide (InGaP).

5. The light-emitting semiconductor according to claim 4, further comprising a current flow confinement layer disposed between the light-emitting layer and the second P-type semiconductor layer or between the light-emitting layer and the second N-type semiconductor layer, wherein the current flow confinement layer comprises a peripheral insulative region and a central conductive region.

6. The light-emitting semiconductor according to claim 5, wherein the peripheral insulative region is disposed right below the cathode electrode.

7. The light-emitting semiconductor according to claim 6, wherein the material of the current flow confinement layer is aluminum arsenide (AlAs), and the peripheral insulative region is formed by oxidizing aluminum (Al) in the current flow confinement layer.

8. The light-emitting semiconductor according to claim 7, wherein the first P-type semiconductor layer comprises a first buffer layer, a second buffer layer, and an anode layer, the first buffer layer is disposed on the upper surface of the substrate, the second buffer layer is disposed on the first buffer layer, and the anode layer is disposed on the second buffer layer.

9. The light-emitting semiconductor according to claim 8, wherein the second N-type semiconductor layer comprises a blocking layer, a cathode layer, and a covering layer, the blocking layer is disposed on an upper surface of the light-emitting layer, the cathode layer is disposed on the blocking layer, and the covering layer is disposed on the cathode layer.

10. A manufacturing method of a light-emitting semiconductor structure, comprising:
forming a cathode electrode on an upper surface of a semiconductor substrate structure, wherein the semiconductor substrate structure comprises a substrate, a first P-type semiconductor layer, a first N-type semiconductor layer, a second P-type semiconductor layer, a second N-type semiconductor layer, a light-emitting layer, a current flow confinement layer, and a highly doped P-type semiconductor layer, the first P-type semiconductor layer is disposed on an upper surface of the substrate, the first N-type semiconductor layer is disposed on the first P-type semiconductor layer, the second P-type semiconductor layer is disposed on the first N-type semiconductor layer, the second N-type semiconductor layer is disposed on the second P-type semiconductor layer, the light-emitting layer is disposed between the second P-type semiconductor layer and the second N-type semiconductor layer, the current flow confinement layer is disposed between the light-emitting layer and the second P-type semiconductor layer, and the highly doped P-type semiconductor layer is disposed between the light-emitting layer and the current flow confinement layer;
forming a protective layer on exposed surfaces of the cathode electrode and the semiconductor substrate structure;
performing a first dry etching step to form a first trench on one of two sides of a predetermined light-emitting part of the semiconductor substrate structure and a second trench on the other side of the predetermined light-emitting part of the semiconductor substrate structure, wherein the first trench and the second trench extend from the protective layer to the second P-type semiconductor layer without penetrating through the second P-type semiconductor layer;
oxidizing a side surface of the current flow confinement layer through the first trench and the second trench;
performing a second dry etching step to form a third trench on one of two sides of a predetermined switching part of the semiconductor substrate structure and a fourth trench on the other side of the predetermined switching part of the semiconductor substrate structure, and to allow the second trench to penetrate through the second P-type semiconductor layer and the first N-type semiconductor layer and allow the second trench to extend to the first P-type semiconductor layer without penetrating through the first P-type semiconductor layer, wherein the third trench is formed between the first trench and the predetermined switching part, and the third trench and the fourth trench extend from the protective layer to the second P-type semiconductor layer without penetrating through the second P-type semiconductor layer;
forming a plurality of gate electrodes on a bottom surface of the third trench and a bottom surface of the fourth trench;
performing a third dry etching step to form a fifth trench between two adjacent gate electrodes of the fourth trench, and to allow the second trench to penetrate through the first P-type semiconductor layer and to allow the second trench to extend to the substrate without penetrating through the substrate, wherein the fifth trench extends from the bottom surface of the fourth trench to the first P-type semiconductor layer without penetrating through the first P-type semiconductor layer;
conformally forming a passivation layer on the exposed surfaces of the cathode electrode and the semiconductor substrate structure and on exposed surfaces of the gate electrodes after the third dry etching step;
performing a fourth dry etching step after depositing the passivation layer on the exposed surfaces of the cathode electrode and the semiconductor substrate structure and on the exposed surfaces of the gate electrodes to form a cathode opening above the cathode electrode and a gate opening above each of the gate electrodes; and
forming a circuit layer on the passivation layer, wherein the circuit layer is electrically connected to the cathode electrode via the cathode opening and electrically connected to the gate electrode via the gate opening.
